(19) United States
(12) Patent Application Publication
(10) Pub. No.: US 2010/0065312 A1
(43) Pub. Date: Mar. 18, 2010

(54) Substrate for window ball grid array package

(76) Inventors: Hung-Hsiang Cheng, Kaohsiung (TW); Chih-Yi Huang, Kaohsiung (TW)

Correspondence Address: MCCRACKEN & FRANK LLP, 311 S. WACKER DRIVE, SUITE 2500, CHICAGO, IL, 60606, US

(21) Appl. No.: 12/584,078

(22) Filed: Aug. 31, 2009

(30) Foreign Application Priority Data
Sep. 18, 2008 (TW) 097135866

(51) Int. Cl. H05K 1/09; H05K 1/11; H05K 1/16

(52) U.S. Cl. 174/257; 174/261; 174/260

(57) ABSTRACT

The present invention relates to a substrate for a window ball grid array package. The substrate has at least one window, a plurality of fingers and at least one power/ground section (or power/ground ring). The window penetrates the substrate. The fingers are disposed at the periphery of the window. The power/ground section (or power/ground ring) is disposed between the fingers and the window. The power/ground section (or power/ground ring) is connected to a power/ground voltage so that the power/ground section (or power/ground ring) can improve the smoothness of the current and power integrity, and reduce the heat generation.

### BACKGROUND OF THE INVENTION

1. Field of the Invention

The present invention relates to a substrate for a package, and more particularly to a substrate for a window ball grid array package.

2. Description of the Related Art

FIG. 1 shows a top view of a conventional substrate for a window ball grid array (WBGA) package. The conventional substrate 1 comprises a window 11, a plurality of power/ground planes 12, a plurality of fingers 13, a plurality of I/O ball pads 14, a plurality of power/ground ball pads 15 and a plurality of conductive traces 16. The fingers 13 are disposed at the periphery of the window 11. Each power/ground plane 12 has a plurality of grid holes 121. The material of the power/ground planes 12 is copper. The grid holes 121 are formed by etching a large area made of copper.

The I/O ball pads 14 are electrically connected to some of the fingers 13 by some of the conductive traces 16. The power/ground ball pads 15 are disposed on the power/ground planes 12, and the power/ground planes 12 are electrically connected to the other fingers 13 by the other conductive traces 16. The fingers 13 are electrically connected to a chip (not shown) by a plurality of wires (not shown), and a plurality of solder balls (not shown) are formed on the I/O ball pads 14 and the power/ground ball pads 15.

The disadvantage of the conventional substrate 1 is described below. The ground signal is designed and disposed in an area, and the power signal, which is different, is designed and disposed in another area, that is, the ground and power signals have different properties and are designed and disposed individually, so that power integrity is reduced.

Therefore, it is necessary to provide a substrate for a window ball grid array package to solve the above problem.

### SUMMARY OF THE INVENTION

The present invention is directed to a substrate for a window ball grid array package. The substrate comprises at least one window, a plurality of fingers and at least one power/ground section (or power/ground ring). The window penetrates the substrate. The fingers are disposed at the periphery of the window. The power/ground section (or power/ground ring) is disposed between the fingers and the window, and is connected to a power/ground voltage so that the power/ground section (or power/ground ring) can improve the smoothness of the current and power integrity, and reduce the heat generation.

### BRIEF DESCRIPTION OF THE DRAWINGS

FIG. 1 is a top view of a conventional substrate for a window ball grid array (WBGA) package;

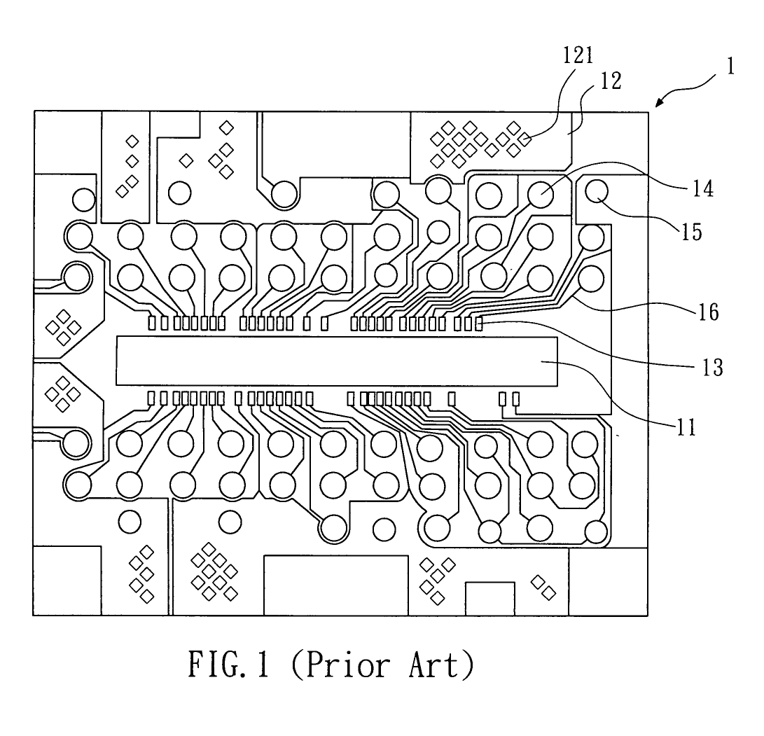

FIG. 2 is a top view of a substrate for a window ball grid array package according to a first embodiment of the present invention;

FIG. 3 is a top view of a substrate for a window ball grid array package according to a second embodiment of the present invention;

FIG. 4 is a top view of a substrate for a window ball grid array package according to a third embodiment of the present invention;

FIG. 5 is a top view of a substrate for a window ball grid array package according to a fourth embodiment of the present invention; and

FIG. 6 is a top view of a substrate for a window ball grid array package according to a fifth embodiment of the present invention.

### DETAILED DESCRIPTION OF THE INVENTION

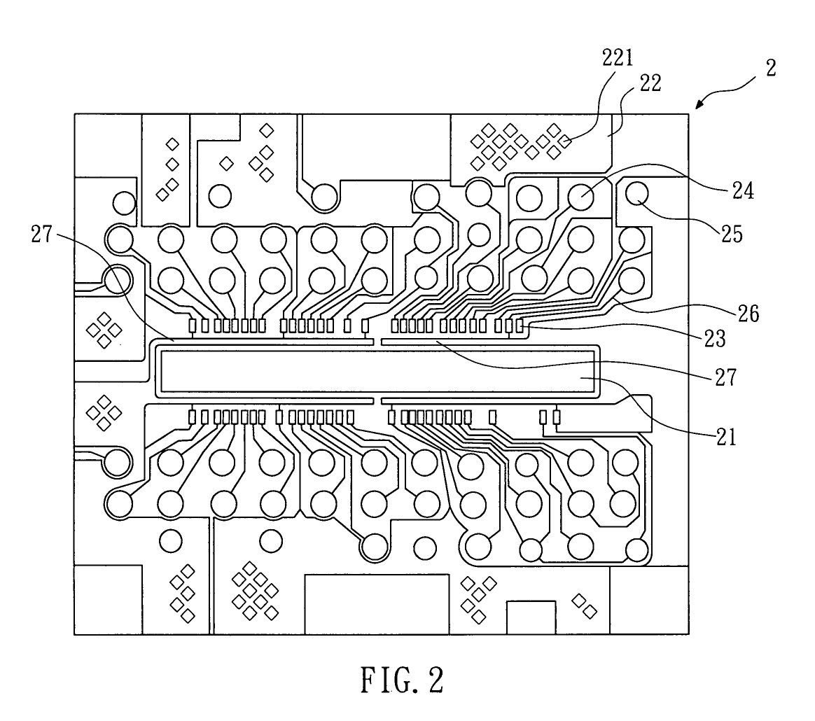

FIG. 2 shows a top view of a substrate for a window ball grid array (WBGA) package according to a first embodiment of the present invention. The substrate 2 comprises a window 21, a plurality of power/ground planes 22, a plurality of fingers 23, a plurality of I/O ball pads 24, a plurality of power/ground ball pads 25, a plurality of conductive traces 26 and at least one power/ground section 27.

The fingers 23 are disposed at the periphery of the window 21. The I/O ball pads 24 are electrically connected to some of the fingers 23 by some of the conductive traces 26. The power/ground ball pads 25 are disposed on the power/ground planes 22, and the power/ground planes 22 are electrically connected to the other fingers 23 by the other conductive traces 26. The fingers 23 are electrically connected to a chip (not shown) by a plurality of wires (not shown), and a plurality of solder balls (not shown) are formed on the I/O ball pads 24 and the power/ground ball pads 25.

Each power/ground plane 22 has a plurality of grid holes 221. Preferably, the material of the power/ground planes 22 is copper, and the grid holes 221 are formed by etching a large area made of copper.

The power/ground section 27 is disposed between the fingers 23 and the window 21, and is connected to a power/ground voltage. The power/ground section 27 is electrically connected to some of the fingers 23. However, in another application, the power/ground section 27 may be electrically connected to a chip (not shown) directly, that is, a plurality of wires (not shown) are bonded to the power/ground section 27. In the embodiment, the window 21 is a rectangle, and the power/ground sections 27 are two discontinuous sections, and surround the window 21. One of the power/ground sections 27 is connected to the ground voltage, and the other is connected to the power voltage, or both of the power/ground sections 27 are connected to the power/ground voltage. It is understood that the number of the power/ground sections 27 may be three or more. Preferably, the power/ground planes 22 are electrically connected to the power/ground sections 27. Alternatively, the power/ground sections 27 are part of the power/ground planes 22.

The advantage of the present invention is that the power/ground section 27 can improve the smoothness of the current and power integrity, and reduce the heat generation.

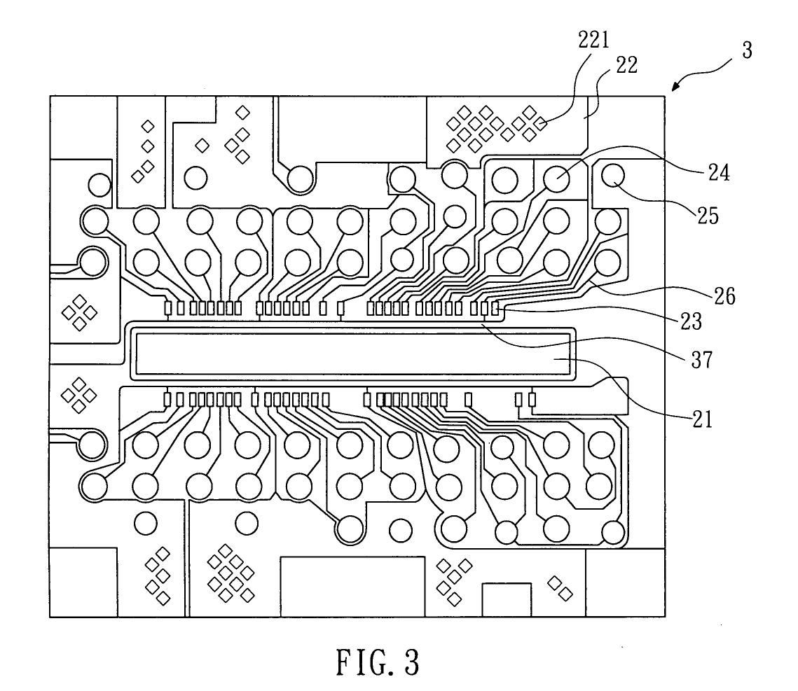

FIG. 3 shows a top view of a substrate for a window ball grid array package according to a second embodiment of the present invention. The substrate 3 of the second embodiment is substantially the same as the substrate 2 (FIG. 2) of the first embodiment, except that the substrate 3 has a power/ground ring 37. In the embodiment, the power/ground ring 37 is annular, and is disposed between the fingers 23 and the window 21. The power/ground ring 37 surrounds the window 21, and is connected to a power/ground voltage. The power/ground ring 37 is electrically connected to some of the fingers 23. However, in another application, the power/ground ring 37 may be electrically connected to a chip (not shown) directly, that is, a plurality of wires (not shown) may be bonded to the power/ground ring 37.

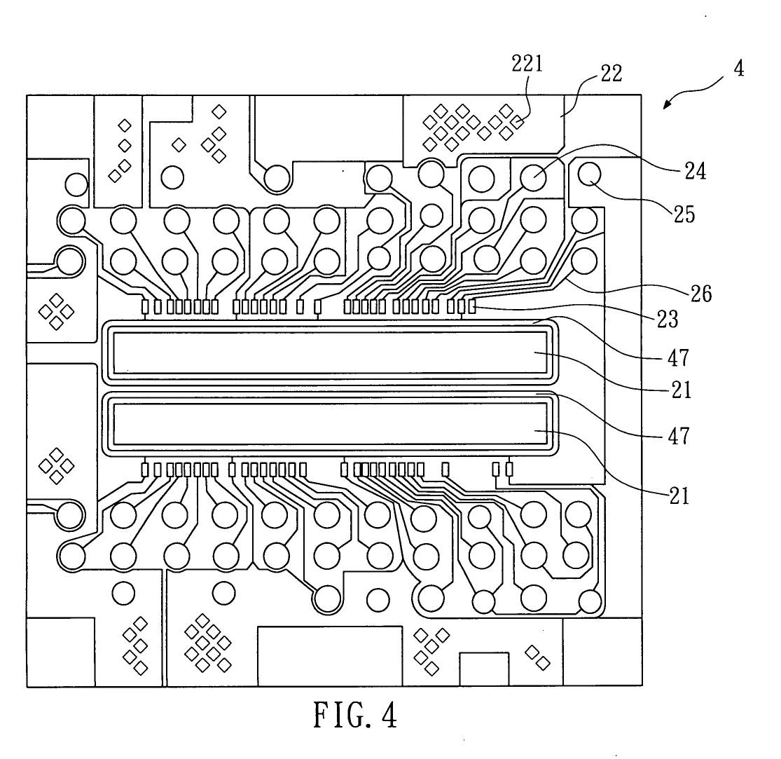

FIG. 4 shows a top view of a substrate for a window ball grid array package according to a third embodiment of the present invention. The substrate 4 of the third embodiment is substantially the same as the substrate 3 (FIG. 3) of the second embodiment, except for the number of windows 21 and power/ground rings 47. In the embodiment, the substrate 4 has two windows 21 and two power/ground rings 47. Each power/ground ring 47 surrounds each window 21. One of the power/ground rings 47 is connected to a ground voltage, and the other is connected to a power voltage, or both of the power/ground rings 47 are connected to the power/ground voltage.

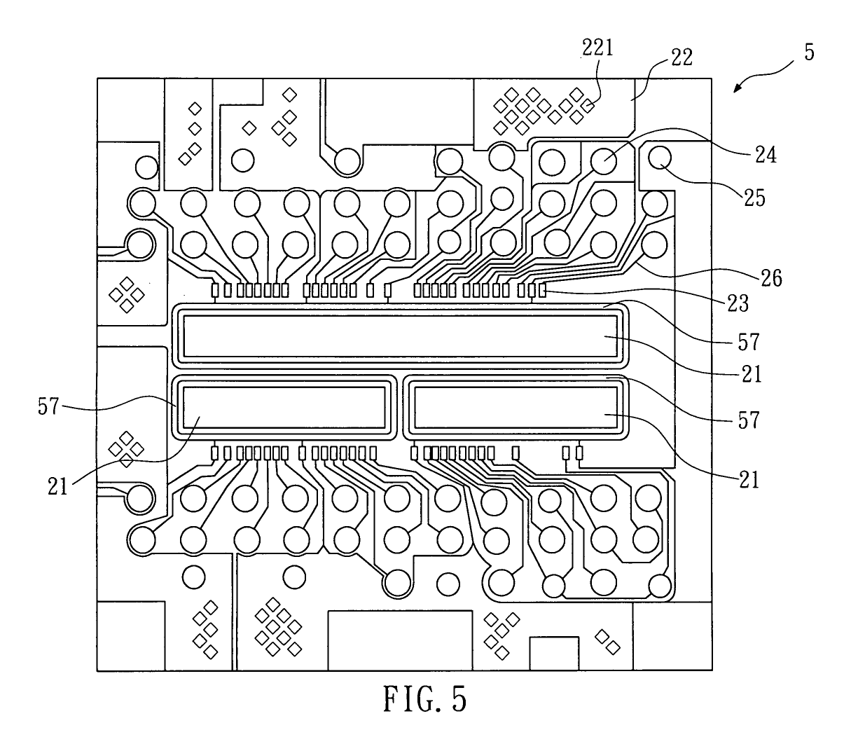

FIG. 5 shows a top view of a substrate for a window ball grid array package according to a fourth embodiment of the present invention. The substrate 5 of the fourth embodiment is substantially the same as the substrate 3 (FIG. 3) of the second embodiment, except for the number of windows 21 and power/ground rings 57. In the embodiment, the substrate 5 has three windows 21 and three power/ground rings 57. Each power/ground ring 57 surrounds each window 21. One of the three power/ground rings 57 is connected to a power/ground voltage, or all of the three power/ground rings 57 are connected to the power/ground voltage.

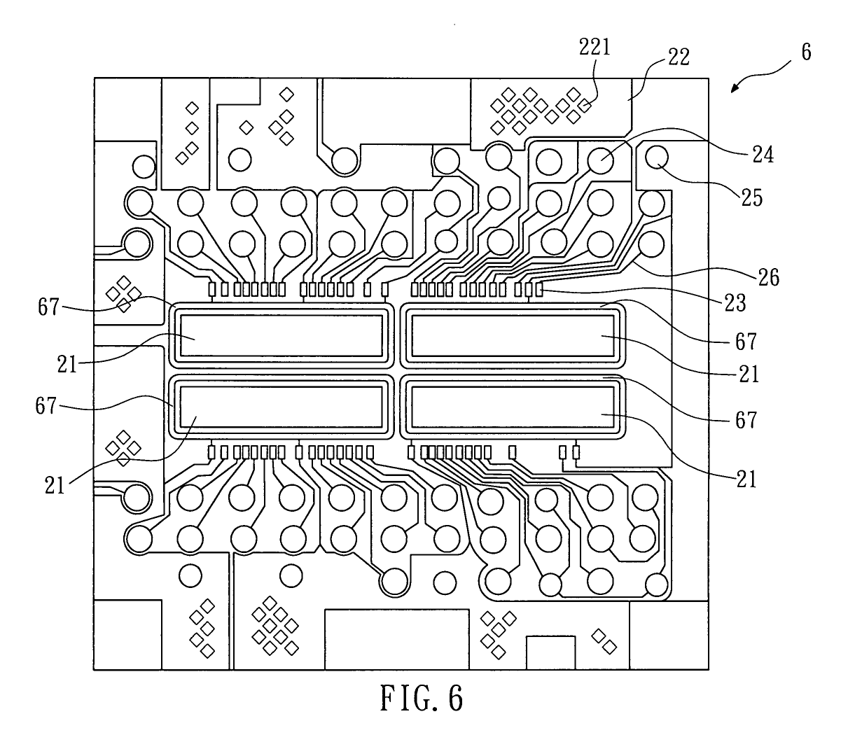

FIG. 6 shows a top view of a substrate for a window ball grid array package according to a fifth embodiment of the present invention. The substrate 6 of the fifth embodiment is substantially the same as the substrate 3 (FIG. 3) of the second embodiment, except for the number of windows 21 and power/ground rings 67. In the embodiment, the substrate 6 has four windows 21 and four power/ground rings 67. Each power/ground ring 67 surrounds each window 21. One of the four power/ground rings 67 is connected to a power/ground voltage, or all of the four power/ground rings 57 are connected to the power/ground voltage.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined in the appended claims.

What is claimed is:

1. A substrate for a window ball grid array package, comprising:
at least one window, penetrating the substrate;
a plurality of fingers, disposed at the periphery of the window; and
at least one power/ground section, disposed between the fingers and the window, that is connected to a power/ground voltage.

2. The substrate-as claimed in claim 1, wherein the window is a rectangle.

3. The substrate as claimed in claim 1, further comprising at least one power/ground plane that has a plurality of grid holes and is electrically connected to the power/ground section.

4. The substrate as claimed in claim 3, wherein the material of the power/ground plane is copper.

5. The substrate as claimed in claim 3, further comprising a plurality of I/O ball pads, a plurality of power/ground ball pads and a plurality of conductive traces, wherein the I/O ball pads are electrically connected to some of the fingers by some of the conductive traces, the power/ground ball pads are disposed on the power/ground plane, and the power/ground plane is electrically connected to the other fingers by the other conductive traces.

6. The substrate as claimed in claim 5, wherein the fingers are electrically connected to a chip, and a plurality of solder balls are formed on the I/O ball pads and the power/ground ball pads.

7. The substrate as claimed in claim 1, wherein the power/ground section is electrically connected to some of the fingers.

8. The substrate as claimed in claim 1, wherein the power/ground section is electrically connected to a chip.

9. A substrate for a window ball grid array package, comprising:
at least one window, penetrating the substrate;
a plurality of fingers, disposed at the periphery of the window; and
at least one power/ground ring, disposed between the fingers and the window, that surrounds the window, and is connected to a power/ground voltage.

10. The substrate as claimed in claim 9, wherein the window is a rectangle.

11. The substrate as claimed in claim 9, further comprising at least one power/ground plane that has a plurality of grid holes and is electrically connected to the power/ground ring.

12. The substrate as claimed in claim 11, wherein the material of the power/ground plane is copper.

13. The substrate as claimed in claim 11, further comprising a plurality of I/O ball pads, a plurality of power/ground ball pads and a plurality of conductive traces, wherein the I/O ball pads are electrically connected to some of the fingers by some of the conductive traces, the power/ground ball pads are disposed on the power/ground plane, and the power/ground plane is electrically connected to the other fingers by the other conductive traces.

14. The substrate as claimed in claim 13, wherein the fingers are electrically connected to a chip, and a plurality of solder balls are formed on the I/O ball pads and the power/ground ball pads.

15. The substrate as claimed in claim 9, comprising a plurality of windows, wherein the number of power/ground rings is the same as that of the windows, and each power/ground ring surrounds each window.

16. The substrate as claimed in claim 9, wherein the power/ground ring is electrically connected to some of the fingers.

17. The substrate as claimed in claim 9, wherein the power/ground ring is electrically connected to a chip.
